(19) United States
(12) Patent Application Publication
(10) Pub. No.: US 2026/0059683 A1
(43) Pub. Date: Feb. 26, 2026

(54) CONVERTER VALVE ASSEMBLY

(71) Applicant: HITACHI ENERGY LTD, Zürich (CH)

(72) Inventors: Bjorn SANDIN, Ludvika (SE); Randee-Chao CHEN, Beijing (CN); Bjorn FRODERBERG, Falun (SE); Daniel NORDIN, Strömsholm (SE); LiHua WU, Beijing (CN); Jennie KAPELL, Ludvika (SE); Sandy-YongYu SHAO, Beijing (CN)

(21) Appl. No.: 19/140,914

(22) PCT Filed: Jan. 20, 2023
(86) PCT No.: PCT/EP2023/051393

§ 371 Date: Jun. 18, 2025

(30) Foreign Application Priority Data
Dec. 19, 2022 (CN) 202211635449.6

(51) Int. Cl. H05K 7/14; H02J 3/36; H02M 7/00; H02M 7/219

(52) U.S. Cl. CPC H05K 7/14324; H02J 3/36; H02M 7/003; H02M 7/219; H05K 7/14339; H02J 2300/28

(57) ABSTRACT

There is disclosed herein a converter valve assembly (20) for a power grid system, comprising two or more equal groups (6a, 6b, 6c) of prismatic converter cells (3a-ad), each group (6a, 6b, 6c) being arranged in a respective plane (7a, 7b, 7c) of a plurality of parallel planes spaced apart along a horizontal axis (8). Converter cells (3a-j) in a group (6a) are connected in series, and the groups (6a, 6b, 6c) are connected in series along the axis (8). The prismatic converter cells (3a-j) in a group (6a) are arranged such that there is a corresponding voltage difference between each converter cell (3a-j) in the group (6a) and each corresponding converter cell (3k-t) in an adjacent group (6b) that is a spatially nearest to said each converter cell (3a-j), during operation of the converter valve assembly (20). Therefore, a spacing between groups may be reduced and an overall volume of the converter valve assembly may be reduced.

### TECHNICAL FIELD

The present disclosure relates to electrical power systems. More particularly, the present disclosure relates to a converter valve assembly for a power grid system, and a method for manufacturing the converter valve assembly.

### BACKGROUND

Power distribution networks comprise converters. The converters are operated to convert an input source voltage (e.g., from a power generation means such as a wind turbine) to an output grid voltage for distribution to a power grid. In some cases, the converters may also convert alternative current (AC) inputs to direct current (DC) outputs, e.g., for a high-voltage DC (HVDC) part of a power grid, or vice versa, e.g., for an AC part of a power grid.

Converters comprise valve assemblies (also referred to as ‘valves’), wherein each valve assembly comprises a plurality of converter cells. Each converter cell typically comprises a full-bridge or half-bridge inverter circuit and contributes a unit of voltage towards the total possible output voltage for the converter. The number of valve assemblies, and/or the number of converter cells, may be chosen based on the required output voltage for the converter.

These valve assemblies are typically housed in a valve hall. For high-voltage applications such as power grid applications, high voltages may be present in the valve hall and, therefore, it is important to ensure that the risk of electrical arcing is suppressed in the valve hall. Furthermore, the size of a valve hall may be limited. This is especially true in the case of off-shore wind, wherein the cost per unit volume of an offshore platform is typically much higher than land-based valve halls. Therefore, the valve assemblies may need to be arranged as close to each other as possible.

Considering these limitations, there is a desire to optimize the arrangement of converter valves within valve halls.

### SUMMARY

It is realized as part of the present disclosure that an optimized, or at least improved, arrangement of converter valves may be realized at least in part through an improvement of the relative arrangement of converter cells to reduce or equalize a voltage difference between spatially adjacent components, wherein the term ‘spatially’ is used to distinguish from ‘electrically’ adjacent components.

Each converter cell in a valve assembly is connected in series and can be considered as contributing a same unit V_{cell} of voltage to the overall output voltage of the converter. Therefore, each converter cell has a voltage difference ΔV of V_{cell} relative to the previous converter cell connected in series thereto.

It is realized as a part of the present disclosure that, when determining a spatial arrangement for the converter cells, it is preferable to minimize this ΔV so as to reduce the risk of electrical arcing between converter cells, and to allow the converter cells to be placed as close to each other as possible, thereby minimizing (or at least reducing) the overall volume of the valve assembly.

Furthermore, it is realized as a part of the present disclosure that a uniform distribution of voltage differences between spatially adjacent converter cells also reduces the risk of electrical arcing between converter cells in the valve assembly.

Therefore, according to an aspect of the present disclosure, there is provided a converter valve assembly for a power grid system, comprising two or more equal groups of prismatic converter cells. That is, each group (or at least two groups) of prismatic converter cells in the converter valve assembly comprises a same number N of prismatic converter cells. As used herein, a ‘prismatic’ converter cell is a converter cell having a three-dimensional form factor with a length, width, and a height, comprising a pair of parallel faces separated by a shortest dimension of said length, width, and a height. For example, the prismatic form factor may comprise a cuboidal form factor, a triangular prism form factor, or a cylindrical form factor.

Each group of the two or more groups is arranged (i.e., spatially arranged) in a respective plane of a plurality of parallel planes spaced apart along a horizontal axis. The converter cells may be arranged and held in place by any suitable support structure, although preferable configurations for such a support structure are described below.

It will be appreciated that the ‘planes’ in which converter cells are arranged may only be defined after said arrangement and by virtue of said arrangement. That is, two or more converter cells may be arranged relative to each other such that a plane intersecting all of said two or more converter cells is defined.

Moreover, it will be appreciated that, while ‘parallel’ planes are referred to, some tolerance away from perfect parallelism is permissible without significantly degrading the advantageous properties of the presently disclosed converter valve arrangement.

By arranging the groups in planes along a horizontal axis, a greater number of groups may advantageously be included in the converter valve arrangement, such that the converter valve assembly may constitute an entire arm of a converter. It will be appreciated that, as used herein, a ‘horizontal’ axis refers to an axis that is substantially perpendicular to the action of gravity.

Therefore, by arranging the groups along a horizontal axis, a single structure may be formed, negating any need for additional spacing between multiple structures. Furthermore, all level points on such a single structure will experience a same gravitational stress and thus it is advantageously simple to scale such a converter valve assembly without adapting a support structure therefor, e.g., as may be required for a vertical structure, which may experience increased gravitational stress at higher levels as a greater number of groups were added.

Converter cells in a group are (electrically) connected to each other in series. The electrical connection between the converter cells may be carried out by any suitable means, and the groups are then connected in series along the axis using, e.g., similar such means for electrical connection.

In some examples, the converter cells may be arranged with their shortest dimension perpendicular to the plane. The shortest dimension of the prismatic converter cells may be any of the length, width, or height of the three-dimensional converter cells that has the least magnitude. For example, if the converter cells have a cuboidal form factor with a length of 30 centimeters (cm), a width of 20 cm, and a height of 10 cm, then the converter cells according to the presently disclosed converter valve assembly are arranged with their height perpendicular to the plane, i.e., the plane that is defined by the relative arrangement of the converter cells. In this example, the length and width of the converter cells extend parallel to the plane.

The relative arrangement of the converter cells within the plane and relative to other groups in parallel planes may be advantageously configured such that a voltage difference between each group's plane can be normalized. Thus, the prismatic converter cells in a group are arranged such that there is a corresponding voltage difference (i.e., a same or substantially similar) between each converter cell in the group and each corresponding converter cell in an adjacent group that is a spatially nearest to said each converter cell, during operation of the converter valve assembly.

Viewed from another perspective, each converter cell in a group has a corresponding converter cell in an adjacent group that is spatially nearest said converter cell, and a voltage difference between each converter cell in a group and its corresponding converter cell in an adjacent group is the same, during operation of the converter valve assembly. That is, the prismatic converter cells in a group are arranged such that there is a corresponding voltage difference between any pair of converter cells, wherein a first converter cell of a pair of said any pair is a converter cell of the group and a second converter cell of said pair is a corresponding converter cell in an adjacent group that is a spatially nearest to said first converter cell, during operation of the converter valve assembly.

Such an arrangement may be achieved by, for example, connecting each group in series from a first converter cell to a last converter cell of the group, according to a cell arrangement common to all groups. In such an example, the last converter cell of the group may be connected to a first converter cell of an adjacent group.

The spacing between different groups of converter cells arranged in different adjacent planes may be determined based at least in part on a risk of electrical arcing between conductors in the different groups having different potential differences. The greater the potential different between conductors (e.g., during operation of the converter valve assembly), the greater the distance that should be provided between said conductors to mitigate said risk of electrical arcing therein between.

Therefore, by arranging the converter cells such that there is a corresponding voltage difference (i.e., a same or substantially similar) between each converter cell in the group and each corresponding converter cell in an adjacent group that is a spatially nearest to said each converter cell, during operation of the converter valve assembly, a spacing between adjacent groups can be reduced (or optimized), and no space is wasted in the converter valve assembly.

Moreover, by arranging the converter cells such that their shortest dimension is perpendicular to the plane, it can be ensured that the spacing between groups (along the axis, perpendicular to the plane) is less likely to be constrained by the dimensions of the converter cells themselves. For example, a spacing S may be determined based on the voltage difference between converter cells in adjacent groups, and this voltage difference may be substantially the same and uniform throughout the plane in which the converter cells are arranged.

For example, the spacing S may be a minimal spacing between groups that mitigates the risk of electrical arcing between said groups. The spacing S may be less than a longest dimension L of the converter cells but greater than a shortest dimension H of the converter cells such that H<S<L. Therefore, by arranging the converter cells with their shortest dimension H perpendicular to the plane, the spacing between groups (i.e., between planes) may be reduced, based on electrical limitations and not spatial limitations.

However, it will be appreciated that a second-shortest dimension of the converter cells (such as a width W) may also satisfy W<S<L. That is, the converter cells may be arranged with a dimension that is less that their longest dimension parallel to the plane and still benefit from the advantageous effects of the present approach.

By optimizing a volume that the converter valve assembly occupies, the overall footprint of a converter station may be reduced. This may be especially beneficial in a case wherein the converter station is installed on an offshore wind installation, because of the very high costs and spatial limitations that are associated with such installations.

In some examples, the cell arrangement may be a helical arrangement, e.g., as viewed in respect of the electrical connections between cells in a group and between groups), such as a horizontal helix wherein the axis of the helix runs horizontally. Put another way, the cell arrangement may comprise arranging the converter cells in the group around the axis, and connecting the converter cells in the group in sequence according to their radial position around the axis, thereby forming an open loop from the first converter cell to the last converter cell of the group. Each open loop may be seen as forming a ‘turn’ of the helix shape.

According to such an arrangement, the conductors used for connecting cells in a group and for interconnecting groups may be shortened. Furthermore, a configuration of the electromagnetic field during operation of the converter valve assembly may be made more uniform so as to further reduce the risk of electrical arcing along paths of concentrated electrical field, for example.

Furthermore, according to some examples, each converter cell in a group may be aligned with a corresponding converter cell in an adjacent group, the corresponding converter cell having a same position in the cell arrangement.

Therefore, the overall volume of the converter valve assembly may be further reduced, as not only the spacing along the axis is reduced, but also perpendicular to the axis, such that an absolute distance between corresponding pairs of converter cells (having a same respective position in the arrangement) can be reduced or minimized.

As discussed above, the plurality of parallel planes may be spaced apart along the axis by a spacing corresponding to the voltage difference between said each converter cell in the group and said each corresponding converter cell in the adjacent group. That is, a minimum ‘safe’ distance may be calculated based on the voltage difference between corresponding converter cells in adjacent groups, and the groups may be spaced apart by this minimum safe distance to thereby reduce the overall volume of the converter valve assembly.

It is appreciated as a part of the present disclosure that seismic events such as earthquakes pose a significant risk to converter valve assemblies. Therefore, according to some examples, each group may be rigidly mounted on a respective substructure. Thus, during seismic events, converter cells within a same group are prevented from moving relative to one another, thereby reducing the risk of electrical arcing within a group or otherwise negatively affecting the operation of the group of converter cells.

According to some further examples, each substructure may be rigidly connected along the axis to thereby form a support structure for the converter valve assembly. Therefore, during seismic events, different groups are prevented from moving relative to one another, thereby reducing the risk of electrical arcing between groups or otherwise negatively affecting the operation of the converter valve assembly. The substructures may be rigidly connected by an insulating member, so as to further enhance the electrical insulation between groups.

The converter valve assembly may further comprise a mounting assembly for the support structure. The mounting assembly may comprise a suspension assembly for suspending the support structure from a ceiling or a standing assembly for raising the support structure from a floor.

By suspending the support structure from the ceiling of a valve hall, seismic events may pose less of a risk to the structure of the converter valve assembly, because the seismic motion can be absorbed or mitigated by a swinging or other compensatory motion of the hanging support structure.

However, if the support structure is mounted on a standing assembly, installation may be simplified, and access to the converter valve assembly may be improved.

Such a standing assembly may comprise a plurality of posts configured to provide electrical insulation from the floor, and each substructure may be mounted on a respective one or more posts or, alternatively, a plurality of substructures may be mounted via a common mounting structure.

In order to reduce the risk of electrical arcing or other electromagnetic interference between the converter valve assembly and external hazards (such as walls, columns, other electrical components, etc.), a shielding structure may be provided such as corona shielding.

According to some examples, a shielding structure may be provided for each group, arranged in the plane. Such an arrangement may advantageously reduce the overall amount of shielding required to shield the converter valve assembly from an outside environment and vice versa.

In preferred embodiments, the converter valve assembly may constitute an arm of a converter. That is, the two or more groups of converter cells that constitute the converter valve assembly may comprise all of the converter cells of an entire arm of a converter. Therefore, the arm may advantageously be formed as a single unit, which may thus have a single structure. Compared to a comparative example whereby a plurality of separate structures, each forming a ‘sub-arm’, are used to constitute an arm of a converter, an advantageously robust system is provided, especially in respect of seismic events. The converter may be a modular multilevel converter configured to provide power to a power grid, for example.

According to a further aspect of the present disclosure, there is provided a method of manufacturing the converter valve assembly substantially as described above. The method comprises arranging two or more equal groups of prismatic converter cells such that each group is arranged in a respective plane of a plurality of parallel planes spaced apart along an axis. As a result of such arranging, converters cell in a group are connected in series, each group is connected in series along the axis, and the arrangement of the prismatic converter cells in a group is configured such that there is a corresponding voltage difference between each converter cell in the group and each corresponding converter cell in an adjacent group that is a spatially nearest to said each converter cell, during operation of the converter valve assembly.

The method may be performed by any manual or automatic means, such as through the use of computer-controlled manipulators, which may provide superior precision than could be achieved manually.

In any event, it will be appreciated that numerous advantages are provided through the provision of a converter valve assembly being formed as a series of parallel planes, and allowing for a spacing of these planes apart from each other according to a voltage difference common to all corresponding pairs of converter cells in adjacent groups. Some of these advantages are described above, and some may be made apparent in the following further description of specific embodiments of the present disclosure.

### BRIEF DESCRIPTION OF THE DRAWINGS

One or more embodiments will be described, by way of example only, and with reference to the following figures, in which:

FIG. 1 shows an electrical schematic of an example modular multilevel converter (MMC);

FIG. 2 shows an electrical schematic of an example converter cell configured as a full-bridge submodule;

FIG. 3 schematically shows a perspective view of a prismatic converter cell, according to embodiments of the present disclosure;

FIGS. 4a and 4b show a perspective view and a top view, respectively, of part of a prior art converter valve assembly;

FIG. 5a shows an exploded perspective view of a converter valve assembly, according to an embodiment of the present disclosure;

FIG. 5b shows a top view of one of the groups of converter cells shown in FIG. 5a;

FIG. 6 shows a perspective view of a converter valve assembly, according to an embodiment of the present disclosure;

FIG. 7 shows a perspective view of a converter valve assembly having a shielding structure and a mounting assembly, according to an embodiment of the present disclosure;

FIGS. 8a and 8b show possible alternative configurations for a mounting assembly, according to embodiments of the present disclosure;

FIG. 9 shows a perspective view of part of a support structure for a converter valve assembly, according to an embodiment of the present disclosure;

FIG. 10 shows a perspective view of a converter valve assembly constituting an arm of a converter, according to an embodiment of the present disclosure; and

FIG. 11 illustrates, as an example flow of steps, a method of manufacturing a converter valve assembly according to an embodiment of the present disclosure.

### DETAILED DESCRIPTION

The present disclosure is described in the following by way of a number of illustrative examples. It will be appreciated that these examples are provided for illustration and explanation only and are not intended to be limiting on the scope of the disclosure.

Use of the same reference numeral in different figures may indicated that the component or element referred to is the same or similar at least in respect of function in said different figures. Therefore, discussion of such same or similar components or elements may not be repeated in relation to all figures in which said components or elements are illustrated.

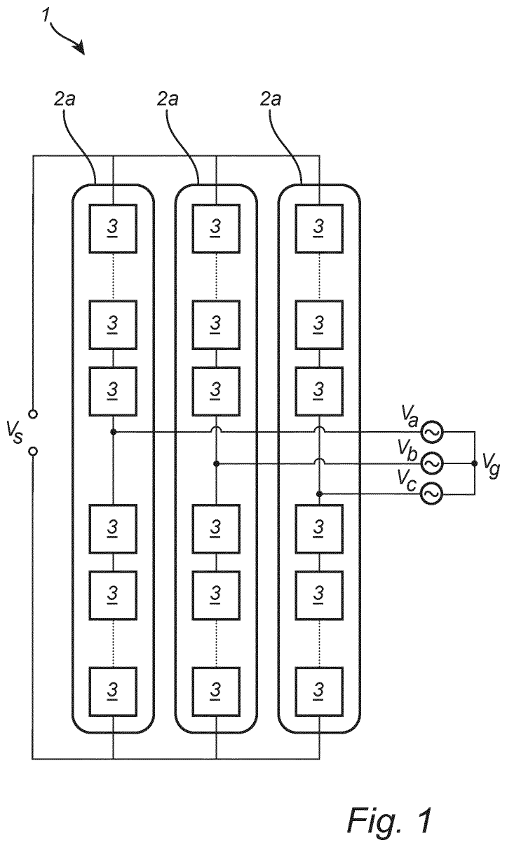

FIG. 1 shows an electrical schematic of an example modular multilevel converter (MMC) 1. The MMC 1 may be acting as a voltage source converter for a power grid, and may be operated to converter a source voltage Vₛ, which may be alternating current (AC) or direct current (DC), to a grid voltage V_{g}, which may be AC or DC. For example, the power grid on which the MMC 1 is installed may be a high-voltage DC (HVDC) power grid.

The source voltage Vₛ may originate from any suitable source of generated and/or stored electrical energy. For example, the source voltage Vₛ may be provided from one or more wind turbines and/or one or more energy storage systems comprising storage capacitors and/or storage batteries. The grid voltage V_{g} may have a predefined magnitude and frequency, based on desired properties of the power grid on which the MMC 1 is installed. Thus, the MMC 1 may be operated so as to provide a source of voltage in accordance with these desired properties for the grid voltage V_{g}. The illustrated MMC 1 outputs a grid voltage V_{g} as a(n approximated) sine wave having a frequency and amplitude.

The MMC 1 comprises a plurality of arms 2a, 2b, 2c, which may be collectively or generally referred to as ‘arms 2’. Each arm 2 corresponds to a different phase Vₐ, V_{b}, V_{c} of the output grid voltage Vₛ, such that the three arms 2 result in a three-phase grid voltage V_{g}, each phase being separated by substantially 120 degrees of phase.

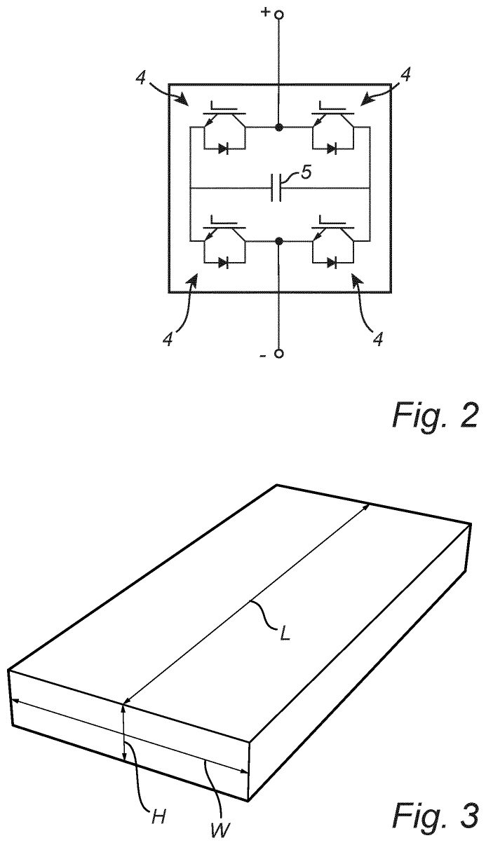

Each arm 2 of the MMC 1 comprises a plurality of converter cells 3, which may also be referred to as ‘submodules 3’. Each converter cell 3 comprises a half-bridge or full-bridge switching circuit arranged around a capacitor. An example of a full-bridge converter cell 3 is shown in FIG. 2, wherein a plurality of semiconductor switches 4 are arranged in a full-bridge configuration around a capacitor 5.

Each converter cell 3 can therefore be switched on and off according to a switching pattern through a coordinated control of the semiconductor switches 4 of each converter cell 3, such that the capacitor 5 may be discharged in a positive or negative direction, relative to the contribution to the overall grid voltage Vₛ that the phase to which the arm 2, in which the converter cell 3 is situated, is contributing.

Each converter cell 3, or at least a plurality of converter cells 3, may be configured with a similar capacitor 5 such that each converter cell 3 has an equal magnitude of contribution in respect of its voltage. That is, when switched into or out of the overall output grid voltage V_{g} (to thereby form a substantially sinusoidal output), it can be said that the discharge of the capacitor 5 from each converter cell 3 contributes a same (or at least substantially the same) voltage. This voltage difference contributed by each converter cell 3 can be referred to as ΔV.

In order to approximate a sinusoidal signal more closely, a greater number of converter cells 3 per arm 2 may be used, with each converter cell 3 contributing a relatively lower ΔV. If N converter cells 3 are included in each arm 2 to output respective phases of the grid voltage V_{g}, then ΔV may be configured as V_{g} divided by N.

Each arm 2 of the MMC 1 may be constituted by one or more converter valve assemblies.

While a MMC is discussed herein, it will be appreciated that the present disclosure may relate to substantially any type of converter having a plurality of converter cells.

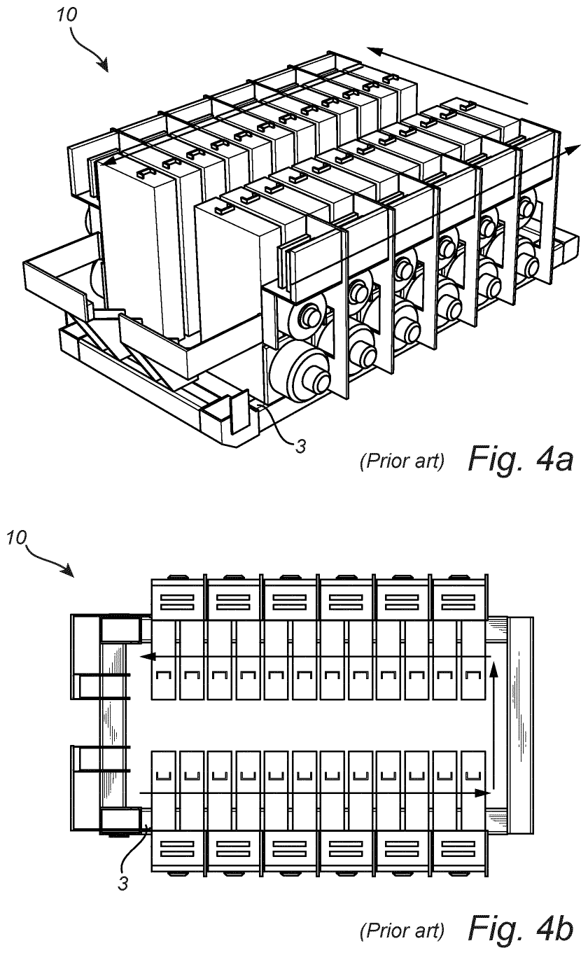

FIG. 3 schematically shows a perspective view of a prismatic converter cell 3. The prismatic converter cell has a length L, a width W, and a height H, these labels being arbitrarily assigned and thus being interchangeable.

In some alternative implementations of the present disclosure, the converter cell 3 may have a different shape, e.g., comprising triangular faces or circular faces (i.e., being cylindrical). That is, the converter cell 3 may have a three-dimensional (3D) form factor with a shortest dimension of a height, width, and length, wherein the shortest dimension may be equal to the longest or second-longest dimension.

The illustrated converter cell 3 is cuboidal, having a height H less than its width W, which is in turn less than its length L. Thus, it can be seen that the shortest dimension of the illustrated prismatic converter cell 3 is its height H.

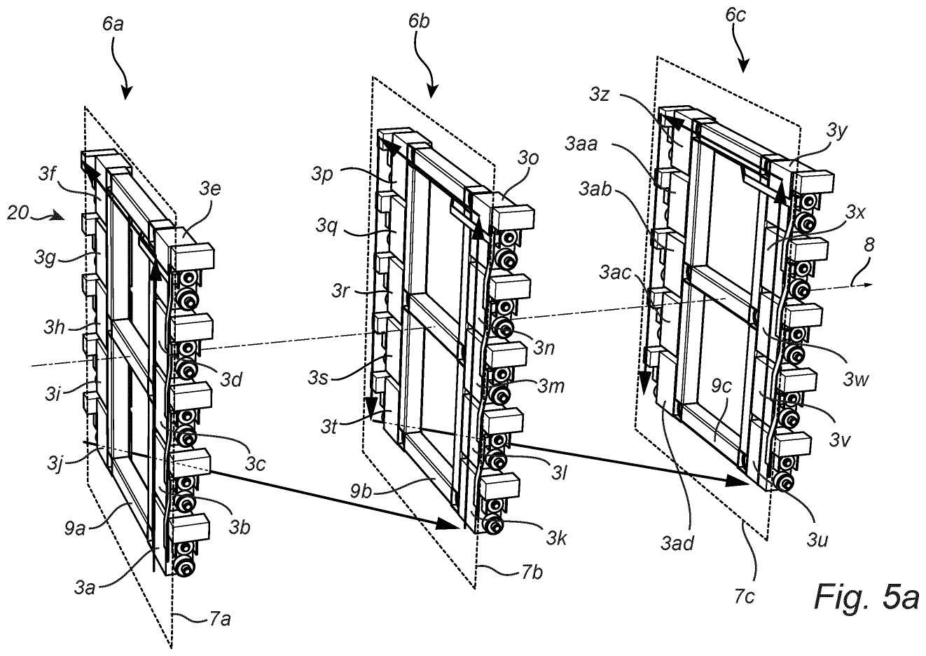

FIGS. 4a and 4b illustrate a prior art converter valve assembly arrangement 10, wherein a plurality of convert cells 3 are arranged in a layer. According to such a prior art arrangement, a plurality of such layers may be stacked on top of each other to thereby form a part of a converter arm. A plurality of such stacks may thus constitute an arm of a converter.

The twenty-four converter cells 3 in the layer are arranged in two columns and connected in series, as indicated by the solid arrows, such that the first and last connected cells 3 neighbor each other and have a voltage difference relative to each other of 24ΔV. Therefore, the spacing between the two columns needs to be configured based on this voltage difference so as to reduce the risk of electrical arcing or other interference effects between the first and last series-connected cells 3. Similar considerations may apply to the spacing between layers in a stack, and/or spacing between stacks.

However, it will be appreciated that such a spacing may waste space, as not all cells 3 in the layer have this same voltage difference relative to their spatial nearest neighbor(s). Indeed, at the opposite end of the columns (i.e., furthest away as illustrated in FIG. 4a), the cells 3 opposed on either side of the columns are directly connected to each other, so do not require a spacing between them configured to prevent electrical arcing between cells 3 having a voltage difference of 24ΔV.

Moreover, the vertical stacking of such layers may place a structural limit on the number of cells 3 that can be included in a converter valve assembly. Put another way, ‘vertical stacking’ may be considered as arranging the prismatic cells with their longest dimension perpendicular to the plane in which they are arranged. Thus, a plurality of such vertically-arranged converter valve assemblies may be required (which may be referred to as ‘sub-arms’) to constitute an arm of a converter. During seismic events (e.g., earthquakes), these sub-arms may be displaced relative to each other and damage the operation of the converter.

Therefore, according to an aspect of the present disclosure, there is provided a converter valve assembly that overcomes at least some of these problems in the prior art converter valve assemblies such as that shown in FIGS. 4a and 4b.

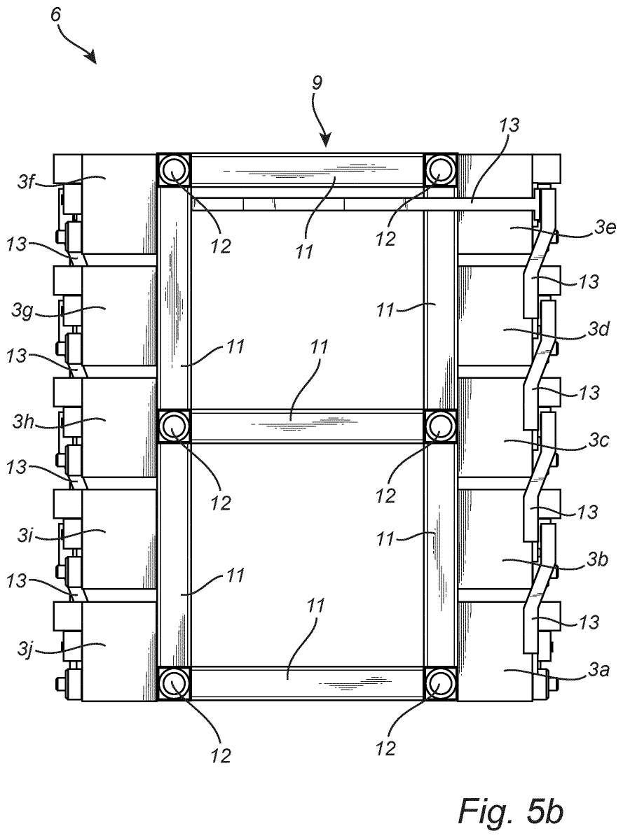

FIGS. 5a and 5b show an embodiment of a converter valve assembly 20 according to an aspect of the present disclosure.

According to the illustrated embodiment, the converter valve assembly 20 comprises three equal groups 6a, 6b, 6c, of prismatic converter cells 3a-ad (which may be referred to generally as ‘converter cells 3’). That is, the thirty illustrated converter cells 3 are distributed evenly such that ten converter cells 3 are arranged in each group 6a, 6b, 6c. Group 6a comprises converter cells 3a-j, group 6b comprises converter cells 3l-3t, and group 6c comprises converter cells 3u-3ad.

Each group 6a, 6b, 6c of converter cells 9 is arranged in a respective plane 7a, 7b, 7c. That is, for example, the converter cells 3a-3j are arranged such that a plane 7a is defined by their relative arrangement—the plane 7a intersects all of the converter cells 3a-3j. The planes 7a, 7b, 7c are spaced apart along an axis 8, which is a horizontal axis 8 in this illustrated embodiment. The spacing along the axis 8 is exaggerated in FIG. 5a for the purpose of clear illustration.

Within each group 6a, 6b, 6c, the converter cells 3 are arranged according to an arrangement that is common to all groups 6a, 6b, 6c, and the converter cells 3 are connected in series. In group 6a, the converter cells 3 are connected in series from a first converter cell 3 of the group 6a—converter cell 3a—to a last converter cell 3 of the group 6a—converter cell 3j. In the group 6b, the converter cells 3 are connected from converter cell 3k to 3t, and in the group 6c, the converter cells 3 are connected from converter cell 3u to 3ad.

The groups 6a, 6b, 6c are connected in series along the axis 8, such that a last converter cell 3 of a group 6a, 6b, 6c, is connected to a first converter cell 3 of a proceeding group 6a, 6b, 6c. In FIG. 5a, the last converter cell 3j of the group 6a is connected to the first converter cell 3k of the group 6b, and the last converter cell 3t of the group 6b is connected to the first converter cell 3u of the group 6c.

In the illustrated example, the arrangement of the converter cells 3 is such as to form a helical shape, as indicated by the arrows superimposed onto FIG. 5a. That is, as can be seen in FIG. 5a, the converter cells 3 in the groups 6a, 6b, 6c are arranged around the axis 8 and connected in sequence according to their radial position around the axis 8, thereby forming an open loop from the first converter cells 3 to the last converter cells 3 of the groups 6a, 6b, 6c.

It will be appreciated that, because each of the groups 6a, 6b, 6c has a same arrangement of converter cells 3 in respect of their spatial placement and electrical interconnection, the prismatic converter cells 3 in a group, e.g., the group 6a, are arranged such that there is a corresponding voltage difference between each converter cell 3 in the group 6a and each corresponding converter cell 3 in an adjacent group, e.g. the group 6b, that is spatially nearest to said each converter cell 3, during operation of the converter valve assembly 20.

Put another way, each group 6a, 6b, 6c contains a respective converter cell 3 that is in a corresponding location in the cell arrangement. For example, converter cells 3a, 3k, and 3u are corresponding converter cells 3, converter cells 3e, 3o, and 3y are corresponding converter cells 3, etc. Thus, according to such an arrangement, the voltage difference between converter cell 3a and 3k may correspond (i.e., be the same or substantially similar to) a voltage difference between converter cell 3e and 3o. The same applies to each pair of corresponding converter cells 3 in each adjacent group 6a, 6b, 6c.

In particular, it will be appreciated that, if each converter cell 3 contributes a voltage of ΔV, then converter cells 3a and 3k will have a voltage difference between them of 10 ΔV because there are ten converter cells connected in series between converter cells 3a and 3k (i.e., converter cells 3a-j; all of the converter cells in the group 6a). There is also a voltage difference of 10 ΔV between converter cells 3b and 3l, 3c and 3m, 3d and 3n, and so on, for the same reasoning.

Therefore, a spacing along the axis 8 between the groups 6a and 6b can be determined (and reduced, preferably minimized) based on a distance required to prevent electrical arcing due to a voltage difference of 10 ΔV. Accordingly, as this is the voltage difference between all pairs of corresponding converter cells 3 in groups 6a and 6b, less space will be wasted in the converter valve assembly 20, so the overall volume of the converter valve assembly will be reduced.

Although it is shown in FIG. 5a that each converter cell 3 in each group 6a, 6b, 6c is aligned parallel along the axis 8, it will be appreciated that, in some examples, the groups 6a, 6b, 6c, may be displaced by an amount perpendicular to the axis 8. Moreover, although the planes 7a, 7b, 7c are shown as being perfectly parallel, it will be appreciated that some deviation therefrom can be tolerated while still achieving the advantageous effects of the particular arrangement of the converter cells 3 within the converter valve arrangement 20.

It can be seen in FIG. 5a that each group 6a, 6b, 6c of converter cells 3 is mounted on a respective substructure 9a, 9b, 9c. FIG. 5b shows a top plan view of the group 6a, which shows the substructure 9a on which the group 6a of converter cells 3a-j is rigidly mounted, according to this illustrated example.

In particular, according to the illustrated embodiment, the substructure 9a comprises a plurality of rigid bars 11 and interconnections 12, said interconnections 12 being configured to facilitate mechanical connection between interconnections 12 of another substructure, e.g., substructure 9b along the axis 8 as shown in FIG. 5a.

The particular construction of the substructure 9a may take any suitable form, although all of the converter cells 3a-j of the group 6a are preferably rigidly mounted to the same substructure 9a. Therefore, the converter cells 3a-j may be retained in position relative to each other, such that the spacing between the converter cells 3a-j can be preserved, and therefore the proper operation of the group of the converter cells 3a-j can be maintained.

The converter cells 3a-j are connected in series from converter cell 3a to converter cell 3j, using electrical connections 13. It will be appreciated that, because the converter cells 3a-j are connected in series according to their radial position around the axis 8 (i.e., in a counter-clockwise order as shown in FIG. 5b), the length of the electrical connections 13 may be advantageously shorter.

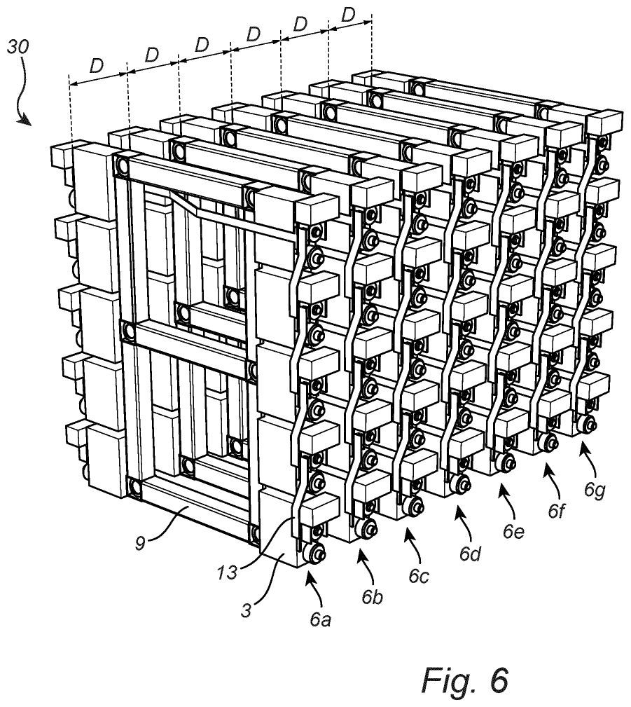

FIG. 6 shows a converter valve assembly 30 comprising a plurality of groups 6a-g, each group 6a-g having a same number of converter cells 3 and being mounted on a respective substructure 9. The arrangement of the cells 3 in groups may be the same or similar to that described in relation to FIGS. 5a and 5b.

The groups 6a-g are arranged in a plurality of parallel planes, and are equally spaced apart along an axis. In the illustrated example, the spacing between each group's plane is a distance D. The distance D may be determined based on a voltage difference between each converter cell in a group (e.g., the group 6a) and each corresponding converter cell in the adjacent group (e.g., the group 6b).

It will be appreciated that the number of cells 3 per group 6a-g may be increased or reduced, depending on the implementation. Furthermore, a number of groups 6a-g may also be varied. In preferred embodiments, if a converter arm is intended to have a number N of converter cells 3, then a number of cells per n groups may be N/n, allowing for some remainder. Therefore, the converter valve assembly 30 may constitute an entire arm of a converter.

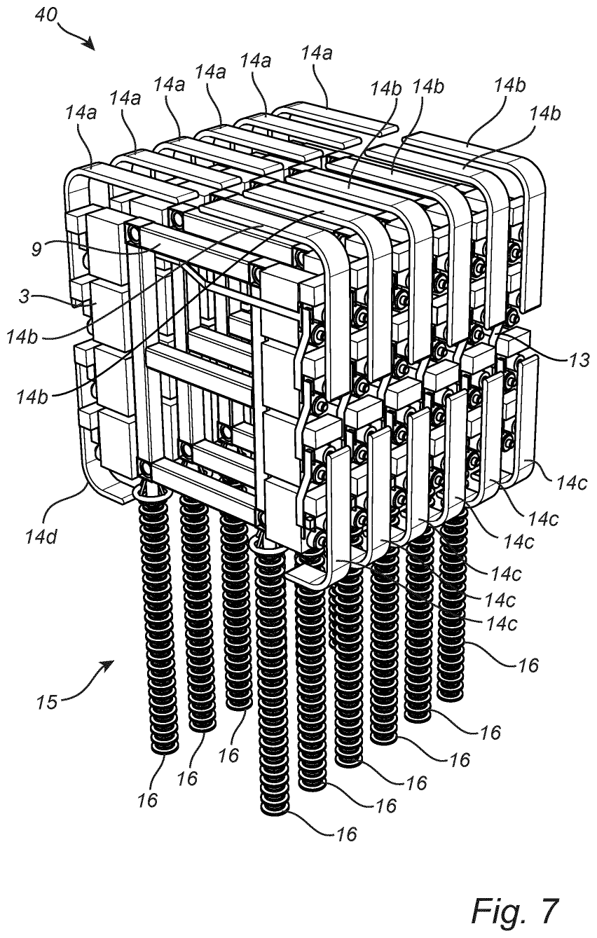

FIG. 7 shows a converter valve assembly 40 having a shielding structure 14a-d and a standing assembly 15 for raising the support structure from a floor (e.g., the floor of a converter hall). The support structure may be formed by the rigid connection of the plurality of substructures 9.

The shielding structure 14a-d comprises a plurality of shielding elements 14a, 14b, 14c, and 14d arranged around each group and within the plane defined by said each group. Therefore, the group of converter cells 3 may be shielded from outside interference, and the outside environment may similarly be shielding from the electromagnetic effects of the converter valve assembly 40. For example, the shielding structure 14a-d may reduce the risk of electrical arcing between the converter valve assembly 40 and its surrounding environment. The shielding structure 14a-d may be made from any suitable material, but preferable a conductive metal.

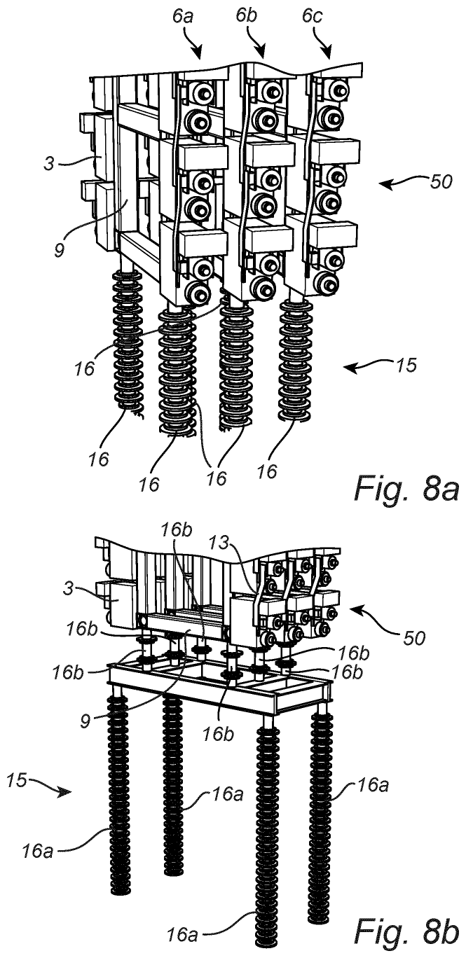

The standing assembly 15 comprises a plurality of posts 16 formed of, and/or coated with, an insulating material. FIGS. 8a and 8b illustrate alternative example configurations of a standing assembly, wherein the configuration shown in FIG. 8a corresponds to that shown in FIG. 7.

In the illustrated examples of FIGS. 7 and 8a, each group 6 of converter cells 3 is mounted on a respective substructure 9, and each substructure 9 is held up by two insulating posts 16. Therefore, the spacing between groups 6 can be established by the relative arrangement of the posts 16.

In the illustrated example of FIG. 8b, a plurality of substructures 9, each having a respective group of converter cells 3 mounted thereon, may be collectively mounted onto a common mounting structure 17 via an intermediate set of posts 16b, e.g., two posts 16a per substructure. The common mounting structure 17 may then be stood on posts 16a.

According to such an arrangement, the insulation between groups may be provided by the insulating posts in the same way as in the example shown in FIGS. 7 and 8a. However, a risk of relative motion of the substructures caused by, e.g., seismic events displacing different pairs of posts 16a by different amounts, is reduced. Therefore, a relative position of groups of converter cells 3 is advantageously preserved by such an arrangement.

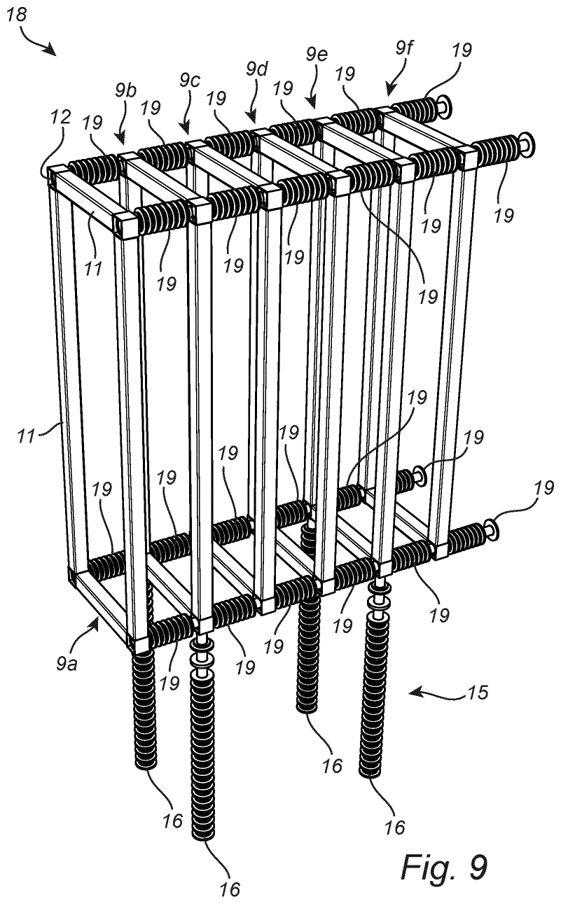

FIG. 9 shows a perspective view of part of a support structure 18 for a converter valve assembly, according to an example embodiment of the present disclosure.

The support structure 18 comprises a plurality of substructures 9a-e similar to those described above, supported by a plurality of posts 16 similar to the posts 16 (or 16a) as described above in relation to FIGS. 7, 8a, and 8b.

The support structure 18 is further configured such that each substructure is rigidly connected to each other by one or more rigid insulating connections 19. Therefore, a rigid and continuous structure can be formed, and fewer vertical supporting posts 16 may be required to raise the support structure 18 from a floor.

Therefore, the same advantageous resilience in the event of, e.g., seismic events as that described in relation to FIG. 8b may be achieved. Moreover, the construction of the support structure 18 may be advantageously simplified.

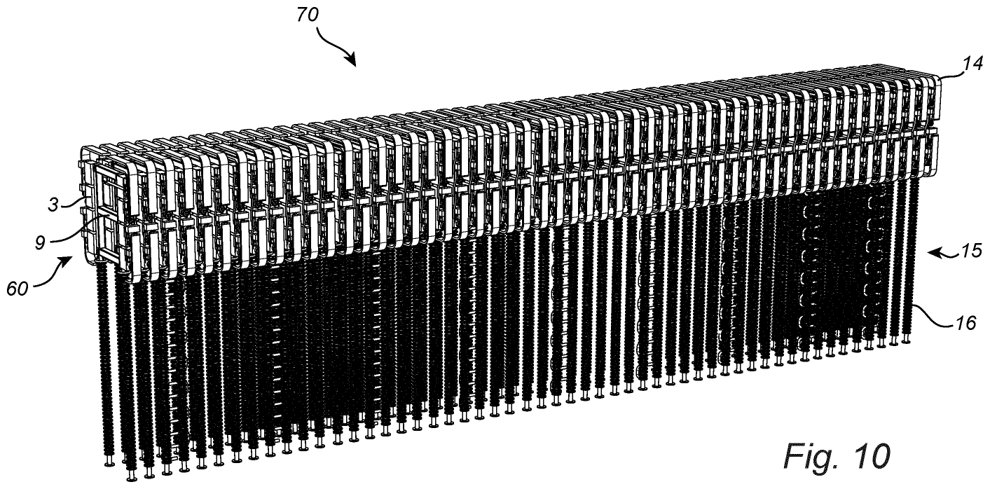

FIG. 10 shows a perspective view of a converter arm 70 formed entirely as a single converter valve assembly 60 supported on a standing assembly 15. It will be appreciated that the amount of shielding structure 14 is significantly less than that which would be required for a plurality of vertically arranged sub-arms such as the arrangement described in relation to FIGS. 4a and 4b.

Although the standing assembly 15 is shown as having two posts 16 per substructure 9, each substructure 9 having a group of converter cells 3 mounted thereon, it will be appreciated that other configurations may be adopted, such as those described in relation to FIG. 8b or 9.

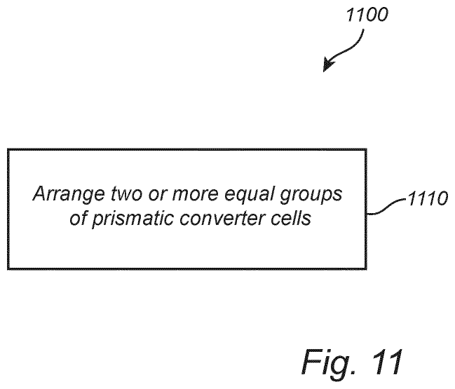

FIG. 11 illustrates a method 1100 of manufacturing a converter valve assembly such as those described above, according to an aspect of the present disclosure.

As illustrated, the method 1100 may comprise arranging two or more equal groups of prismatic converter cells (step 1110) so as to form a converter valve assembly, such that each group is arranged in a respective plane of a plurality of parallel planes spaced apart along an axis.

According to such an arrangement, converter cells in a group are connected in series, each group is connected in series along the axis, and the arrangement of the prismatic converter cells in a group is configured such that there is a corresponding voltage difference between each converter cell in the group and each corresponding converter cell in an adjacent group that is a spatially nearest to said each converter cell, during operation of the converter valve assembly. Such a method may be performed manually or using some robotic manipulator means, depending on the implementation.

While the present disclosure is susceptible to various modifications and alternative forms, specific embodiments are shown and described by way of example in relation to the drawings, with a view to clearly explaining the various advantageous aspects of the present disclosure. It should be understood, however, that the detailed description herein and the drawings attached hereto are not intended to limit the disclosure to the particular form disclosed. Rather, the intention is to cover all modifications, equivalents, and alternatives falling within the scope of the following claims.

1. A converter valve assembly for a power grid system, comprising:
two or more equal groups of prismatic converter cells, each group being arranged in a respective plane of a plurality of parallel planes spaced apart along a horizontal axis,
wherein:
the horizontal axis is substantially perpendicular to the action of gravity;
converter cells in a group are connected in series;
the groups are connected in series along the axis; and
the prismatic converter cells in a group are arranged around the axis and connected in sequence according to their radial position around the axis, such that there is a corresponding voltage difference between each converter cell in the group and each corresponding converter cell in an adjacent group that is spatially nearest to said each converter cell, during operation of the converter valve assembly.

2. The converter valve assembly according to claim 1, wherein: each group is connected in series from a first converter cell to a last converter cell of the group, according to a cell arrangement common to all groups, and the last converter cell of the group is connected to a first converter cell of an adjacent group.

3. The converter valve assembly according to claim 1, wherein: each converter cell in a group is aligned with a corresponding converter cell in an adjacent group, the corresponding converter cell having a same position in the cell arrangement.

4. The converter valve assembly according to claim 1, wherein: the plurality of parallel planes are spaced apart along the axis by a spacing corresponding to the voltage difference between said each converter cell in the group and said each corresponding converter cell in the adjacent group.

5. The converter valve assembly according to claim 1, wherein: each group is rigidly mounted on a respective substructure.

6. The converter valve assembly according to claim 5, wherein: each substructure is rigidly connected along the axis to thereby form a support structure for the converter valve assembly.

7. The converter valve assembly according to claim 6, wherein: substructures are rigidly connected by an insulating member.

8. The converter valve assembly according to claim 6, further comprising a mounting assembly for the support structure, wherein: the mounting assembly comprises a suspension assembly for suspending the support structure from a ceiling or a standing assembly for raising the support structure from a floor.

9. The converter valve assembly according to claim 8, wherein: the standing assembly comprises a plurality of posts configured to provide electrical insulation from the floor.

10. The converter valve assembly according to claim 8, wherein:
each substructure is mounted on a respective one or more posts; or
a plurality of substructures are mounted via a common mounting structure.

11. The converter valve assembly according to claim 1, further comprising: a shielding structure for each group, arranged in the plane.

12. The converter valve assembly according to claim 1, wherein: the converter valve assembly has a single structure constituting an arm of a converter.

13. The converter valve assembly according to claim 1, wherein: the converter is a modular multilevel converter configured to provide power to a power grid.

14. A method of manufacturing the converter valve assembly according to claim 1, comprising:
arranging two or more equal groups of prismatic converter cells such that: each group is arranged in a respective plane of a plurality of parallel planes spaced apart along a horizontal axis,
wherein:
converters cell in a group are connected in series;
each group is connected in series along the axis; and
the arrangement of the prismatic converter cells in a group is configured such that there is a corresponding voltage difference between each converter cell in the group and each corresponding converter cell in an adjacent group that is a spatially nearest to said each converter cell, during operation of the converter valve assembly.

15. (canceled)
